(19) United States
(12) Patent Application Publication
(10) Pub. No.: US 2025/0331375 A1
(43) Pub. Date: Oct. 23, 2025

(54) DISPLAY SUBSTRATE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Wenbo CHEN, Beijing (CN); Ziyang YU, Beijing (CN); Pan ZHAO, Beijing (CN); Quanyong GU, Beijing (CN); Tiaomei ZHANG, Beijing (CN); Erjin ZHAO, Beijing (CN); Mengqi WANG, Beijing (CN); Yujing LI, Beijing (CN); Shilong WANG, Beijing (CN); Zhiliang JIANG, Beijing (CN)

(21) Appl. No.: 18/860,713

(22) PCT Filed: Jan. 2, 2024
(86) PCT No.: PCT/CN2024/070128

§ 371 Date: Jul. 2, 2025

(30) Foreign Application Priority Data
Jan. 3, 2023 (CN) 202310004165.5

(51) Int. Cl. H10K 59/131; H10K 59/121

(52) U.S. Cl. CPC H10K 59/131; H10K 59/121

(57) ABSTRACT

A display substrate, comprising: a base and multiple first lead-out signal lines. The base comprises a display area and a peripheral area surrounding the display area; and the peripheral area comprises a first bezel area located on one side of the display area. The multiple first lead-out signal lines are located in the first bezel area. At least one of the multiple first lead-out signal lines comprises: a first trace, a second trace, and a third trace that are stacked; and the second trace is electrically connected to the first trace and the third trace. The orthographic projection of the first trace on the base, the orthographic projection of the second trace on the base, and the orthographic projection of the third trace on the base at least partially overlap each other.

The present application claims priority of Chinese Patent Application No. 202310004165.5, filed, to the CNIPA on Jan. 3, 2023, and entitled “Display Substrate and Display Device”, the contents of which should be regarded as being incorporated herein by reference.

### TECHNICAL FIELD

The present disclosure relates to, but is not limited to, the field of display technologies, in particular to a display substrate and a display device.

### BACKGROUND

Organic Light Emitting Diodes (OLED) and Quantum-dot Light Emitting Diodes (QLED) are active light emitting display devices, and have advantages of self-illumination, wide viewing angle, high contrast ratio, low power consumption, very high response speed, lightness and thinness, flexibility, and low cost, etc.

### SUMMARY

The following is a summary of subject matter described herein in detail. This summary is not intended to limit the protection scope of claims.

Embodiments of the present disclosure provide a display substrate and a display device.

In one aspect, an embodiment of the present disclosure provides a display substrate, including: a base substrate and a plurality of first lead-out signal lines. The base substrate includes a display area and a peripheral area surrounding the display area, and the peripheral area including a first bezel region located on one side of the display area. The plurality of first lead-out signal lines are located in the first bezel region. At least one first lead-out signal line of the plurality of first lead-out signal lines includes a first trace, a second trace, and a third trace which are stacked, and the second trace is electrically connected with the first trace and the third trace. An orthographic projection of the first trace on the base substrate, an orthographic projection of the second trace on the base substrate, and an orthographic projection of the third trace on the base substrate are at least partially overlapped with each other.

In some exemplary embodiments, the peripheral area further includes a second bezel region located on two sides of the first bezel region; the plurality of first lead-out signal lines includes a plurality of first drive lead-out signal lines. The display substrate further includes: a plurality of sub-pixels located in the display area; a plurality of gate lines located in the display area and electrically connected with the plurality of sub-pixels; a plurality of shift registers located in the second bezel region and electrically connected with the plurality of gate lines, and the plurality of shift registers are electrically connected with the plurality of first drive lead-out signal lines.

In some exemplary embodiments, the display substrate further includes: a plurality of data lines located in the display area. The plurality of first lead-out signal lines include a plurality of first data lead-out lines located in the first bezel region and electrically connected to the plurality of data lines in the display area. The plurality of first data lead-out lines are located between the plurality of first drive lead-out signal lines in the first bezel region.

In some exemplary embodiments, the first bezel region includes: a first sub-region, a bent region, and a second sub-region disposed sequentially along a direction away from the display area; the plurality of first drive lead-out signal lines are located in the first sub-region.

In some exemplary embodiments, the display substrate further includes: a plurality of drive connection lines located in the bent region; the plurality of drive connection lines are electrically connected with the plurality of first drive lead-out signal lines, and the plurality of drive connection lines are on a side of the plurality of first drive lead-out signal lines away from the base substrate.

In some exemplary embodiments, a drive connection line is electrically connected with a first trace, a second trace, and a third trace of a corresponding first drive lead-out signal line through a first connection electrode; the first connection electrode is on a side of the first trace, the second trace, and the third trace of the corresponding first drive lead-out signal line away from the base substrate.

In some exemplary embodiments, the display substrate further includes: a plurality of second drive lead-out signal lines located in the second sub-region. The plurality of second drive lead-out signal lines are electrically connected with the plurality of first drive lead-out signal lines through the plurality of drive connection lines.

In some exemplary embodiments, at least one second drive lead-out signal line of the plurality of second drive lead-out signal lines includes: a fourth trace, a fifth trace, and a sixth trace which are stacked; the fourth trace and the first trace are disposed in a same layer, the fifth trace and the second trace are disposed in a same layer, and the sixth trace and the third trace are disposed in a same layer.

In some exemplary embodiments, the third trace of the first lead-out signal line is on a side of the second trace away from the base substrate, and the first trace is on a side of the second trace close to the base substrate; a width of the first trace of the first lead-out signal line is larger than a width of the second trace, and the width of the second trace is larger than a width of the third trace.

In some exemplary embodiments, the third trace of the first lead-out signal line is on a side of the second trace away from the base substrate, and the first trace is on a side of the second trace close to the base substrate; a width of the second trace of the first lead-out signal line is larger than a width of the first trace, and the width of the first trace is larger than a width of the third trace.

In some exemplary embodiments, the first trace of the first lead-out signal line is located in a first gate metal layer, the second trace is located in a second gate metal layer, and the third trace is located in a third gate metal layer; the first gate metal layer, the second gate metal layer, and the third gate metal layer are located in different layers.

In some exemplary embodiments, the display substrate further includes: a second power supply line located in the first bezel region; in the first sub-region, an orthographic projection of the second power supply line on the base substrate is not overlapped with orthographic projections of the plurality of first drive lead-out signal lines on the base substrate, and the second power supply line is on a side of the plurality of first drive lead-out signal lines away from the base substrate.

In some exemplary embodiments, the display substrate further includes: a second power supply auxiliary line located in the first sub-region of the first bezel region; the second power supply line in the first sub-region includes: a first sub-power supply line and a second sub-power supply line, the first sub-power supply line and the second sub-power supply line are electrically connected through the second power supply auxiliary line; an orthographic projection of the second power supply auxiliary line on the base substrate is at least partially overlapped with the orthographic projections of the plurality of first drive lead-out signal lines on the base substrate.

In some exemplary embodiments, the second power supply auxiliary line is on a side of the first sub-power supply line and the second sub-power supply line away from the base substrate.

In some exemplary embodiments, the second power supply auxiliary line is located in a second source-drain metal layer, the first sub-power supply line and the second sub-power supply line are located in a first source-drain metal layer, and the first source-drain metal layer and the second source-drain metal layer are located in different layers.

In another aspect, an embodiment of the present disclosure provides a display device, which includes the aforementioned display substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a portion of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, but are only intended to schematically describe contents of the present disclosure.

FIG. 1 is a schematic diagram of a structure of a display device.

FIG. 2 is a schematic plan view of a display substrate.

FIG. 3 is a schematic diagram of a partial sectional structure of a display area of a display substrate.

FIG. 4 is a schematic diagram of a first bezel region according to at least one embodiment of the present disclosure.

FIG. 5 and FIG. 6 are schematic partial enlarged diagrams of region U1 in FIG. 4.

FIG. 7 is a schematic partial cross-sectional view taken along a Q-Q′ direction in FIG. 6.

FIGS. 8 and 9 are schematic cross-sectional views of a first drive lead-out signal line according to at least one embodiment of the present disclosure.

FIG. 10 is a schematic diagram of a connection between a first drive lead-out signal line of a first sub-region and a bent connection line of a bent region according to at least one embodiment of the present disclosure.

FIG. 11 is a schematic diagram of a first bezel region after a first source-drain metal layer is formed in FIG. 10.

FIG. 12 is a schematic diagram of a first bezel region after a fifth insulation layer is formed in FIG. 10.

FIG. 13 is a partial schematic diagram of a first bezel region after a third gate metal layer is formed in FIG. 10.

FIG. 14 is a partial schematic diagram of a first bezel region after a second gate metal layer is formed in FIG. 10.

FIG. 15 is a partial schematic diagram of a first bezel region after a first gate metal layer is formed in FIG. 10.

FIG. 16 is a schematic partial cross-sectional view along a R-R′ direction in FIG. 12.

FIG. 17 is a partial schematic diagram of a region U2 in FIG. 4.

FIG. 18 is a schematic partial cross-sectional view of a second drive lead-out signal line according to at least one embodiment of the present disclosure.

### DETAILED DESCRIPTION

The embodiments of the present disclosure will be described below with reference to the drawings in detail. Implementations may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between constituent elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements with reference to the accompanying drawings, not to indicate or imply that involved devices or elements are required to have specific orientations and be structured and operated with the specific orientations but only for ease and simplification of description of the present specification, and thus should not be understood as limitations on the present disclosure. The positional relationships between the constituent elements are changed as appropriate according to directions for describing the constituent elements. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, an “electrical connection” includes a case that constituent elements are connected together through an element with a certain electrical action. The “element with a certain electrical effect” is not particularly limited as long as electrical signals between the connected constituent elements may be transmitted. Examples of the “element having some electrical function” not only include an electrode and a wiring, but also include a switching element such as a transistor, a resistor, an inductor, a capacitor, another element with multiple functions, etc.

In the specification, a transistor refers to an element which at least includes three terminals, i.e., a gate electrode, a drain electrode, and a source electrode. The transistor has a channel region between the drain electrode (drain electrode terminal, drain electrode region, or drain) and the source electrode (source electrode terminal, source electrode region, or source), and a current can flow through the drain electrode, the channel region, and the source electrode. In the specification, the channel region refers to a region through which a current mainly flows.

In the specification, a first electrode may be a drain and a second electrode may be a source, or, a first electrode may be a source and a second electrode may be a drain. In a case that transistors with opposite polarities are used, or in a case that a direction of a current is changed during operation of a circuit, or the like, functions of the “source electrode” and the “drain electrode” are sometimes interchangeable. Therefore, the “source electrode” and the “drain electrode” are interchangeable in the specification. In addition, a gate may also be referred to as a control electrode.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In this specification, a circle, oval, triangle, rectangle, trapezoid, pentagon or hexagon, etc. is not strictly defined, but may be an approximate circle, oval, triangle, rectangle, trapezoid, pentagon or hexagon, etc. Some small deformations due to tolerances may exist, for example, lead angles, curved edges and deformations thereof may exist.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present disclosure, “A extends along a B direction” means that A may include a main portion and a secondary portion connected with the main portion, the main portion is a line, a line segment, or a strip-shaped body, the main portion extends along the B direction, and a length of the main portion extending along the B direction is greater than a length of the secondary portion extending along another direction. “A extends along the B direction” in the present disclosure means “the main portion of A extends along the B direction”.

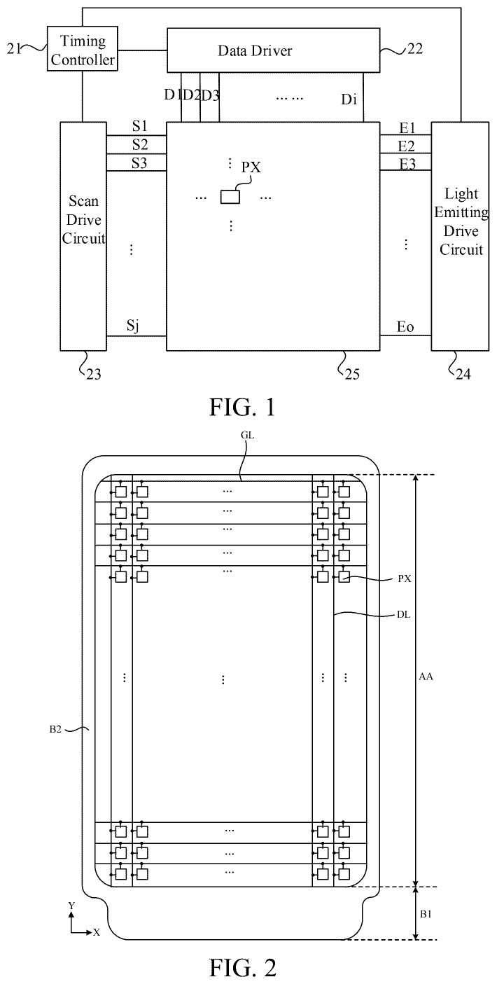

FIG. 1 is a schematic diagram of a structure of a display device. In some examples, as shown in FIG. 1, the display device may include a timing controller 21, a data driver 22, a scan drive circuit 23, a light emitting driver 24, and a sub-pixel array 25. In some examples, the sub-pixel array 25 may include a plurality of sub-pixels PX arranged regularly. The scan drive circuit 23 may be configured to provide a scan signal to a sub-pixel PX along a scan line. The data driver 22 may be configured to provide a data voltage to a sub-pixel PX along a data line. The light emitting drive circuit 24 may be configured to provide a light emitting control signal to a sub-pixel PX along a light emitting control line. The timing controller 21 may be configured to control the scan drive circuit 23, the light emitting drive circuit 24 and the data driver 22.

In some examples, the timing controller 21 may provide the data driver 22 with a gray-scale value and a control signal suitable for a specification of the data driver 22, the timing controller 21 may provide the scan drive circuit 23 with a scan clock signal, a scan start signal, etc., suitable for a specification of the scan driver 23, and the timing controller 21 may provide the light emitting drive circuit 24 with a light emitting clock signal, a light emitting start signal, etc., suitable for a specification of the light emitting drive circuit 24. The data driver 22 may generate a data voltage to be provided to data lines D1 to Di, using the gray-scale value and the control signal received from the timing controller 21. For example, the data driver 22 may sample the gray-scale value using the clock signal and apply a data voltage corresponding to the gray-scale value to the data lines D1 to Di using a sub-pixel row as a unit. The scan circuit 23 may receive the scan clock signal, the scan start signal, etc., from the timing controller 21 to generate a scan signal to be provided to scan lines S1 to Sj. For example, the scan drive circuit 23 may sequentially provide scan signals with on-level pulses to the scan lines. In some examples, the scan driver 23 may include a shift register and sequentially transmit the scan start signal provided in form of an on-level pulse to a next-stage circuit to generate the scan signal under control of the scan clock signal. The light emitting drive circuit 24 may receive the light emitting clock signal, the light emitting start signal, etc., from the timing controller 21 to generate a light emitting control signal to be provided to light emitting control lines E1 to Eo. For example, the light emitting drive circuit 24 may provide sequentially light emitting control signals with off-level pulses to the light emitting control lines. The light emitting drive circuit 24 may include a shift register, and generate a light emitting control signal by sequentially transmitting a light emitting start signal provided in a form of an off-level pulse to a next-stage circuit under control of the clock signal. Herein, i, j, and o are all natural numbers.

In some examples, the display device may include a display substrate. The scan drive circuit and the light emitting drive circuit may be directly provided on the display substrate. For example, the scan drive circuit may be provided on a left bezel of the display substrate, and the light emitting drive circuit may be provided on a right bezel of the display substrate. Or, each of the left bezel and the right bezel of the display substrate may be provided with a scan drive circuit and a light emitting drive circuit. In some examples, the scan drive circuit and the light emitting drive circuit may be formed together with the sub-pixels in a process of forming the sub-pixels.

In some examples, the data driver may be disposed on an independent chip or printed circuit board to be connected to a sub-pixel through a signal access pin on the display substrate. For example, the data driver may be formed and disposed at a first bezel of the display substrate using a chip on glass, a chip on plastics, a chip on film manner, etc., to be connected to the signal access pin. The timing controller may be arranged separately from or integrally with the data driver. However, the present embodiment is not limited thereto. In some examples, the data driver may be directly disposed on the display substrate.

FIG. 2 is a schematic plan view of a display substrate. In some examples, as shown in FIG. 2, the display substrate may include a display area AA, and a peripheral area surrounding the display area AA. The peripheral area may include a first bezel region B1 located on one side of the display area AA, and a second bezel region B2 located on another side of the display area AA. The second bezel region B2 may be located at least on two sides of the first bezel region B1. The first bezel region B1 may be, for example, a lower bezel of the display substrate, and the bezel region B2 may include an upper bezel, a left bezel, and a right bezel of the display substrate. In some examples, the display area AA may be a flat region including a plurality of sub-pixels PX that form a pixel array, and the plurality of sub-pixels PX are configured to display a dynamic picture or a static image. The display area may be referred to as an effective region. In some examples, the display substrate may be a flexible substrate. Accordingly, the display substrate may be deformable, for example, be crimped, bent, folded, or curled.

In some examples, the second bezel region B2 may include a circuit region, a power supply line region, a crack dam region, and a cutting region which are sequentially disposed along a direction of the display area AA. The circuit region may be connected to the display area AA, and the circuit region may include a gate drive circuit, for example, the gate drive circuit may include a plurality of cascaded shift registers, and the plurality of shift registers may be electrically connected with a plurality of gate lines in the display area AA. The power supply line region is connected to the circuit region and may at least include a low-level power supply line. The low-level power supply line may extend along a direction parallel to an edge of the display area and is connected with a cathode in the display area AA. The crack dam region may be connected to the power supply line region and may at least include a plurality of cracks disposed on a composite insulation layer. The cutting region may be connected to the crack dam region, and may at least include cutting grooves disposed on the composite insulation layer. The cutting grooves are configured such that a cutting device cuts along the cutting grooves respectively after preparation of all film layers of the display substrate is completed.

In some examples, the first bezel region B1 and the second bezel region B2 may be provided with a first isolation dam and a second isolation dam respectively. The first bezel region B1 and the second bezel region B2 may extend in a direction parallel to an edge of the display area to form a ring structure surrounding the display area AA, and the edge of the display area may be an edge of the display area close to the first bezel region or the second bezel region.

In some examples, as shown in FIG. 2, the display area AA may at least include a plurality of sub-pixels PX, a plurality of gate lines GL, and a plurality of data lines DL. The plurality of gate lines GL may extend in a first direction X, and the plurality of data lines DL may extend in a second direction Y. Orthographic projections of the plurality of gate lines GL on the base substrate and orthographic projections of the plurality of data lines DL on the base substrate intersect to form a plurality of sub-pixel regions, and one of the sub-pixels PX is disposed in each sub-pixel region. The plurality of data lines DL are electrically connected with the plurality of sub-pixels PX and the plurality of data lines DL may be configured to provide data signals to the plurality of sub-pixels PX. The plurality of data lines DL may extend to the bind region B1. The plurality of gate lines GL are electrically connected with the plurality of sub-pixels PX and the plurality of gate lines GL may be configured to provide gate control signals to the plurality of sub-pixels PX. In some examples, the gate control signals may include a scan signal and a light emitting control signal.

In some examples, as shown in FIG. 2, the first direction X may be an extension direction (row direction) of the gate lines GL in the display area AA, and the second direction Y may be an extension direction (column direction) of the data lines DL in the display area AA. The first direction X and the second direction Y may be perpendicular to each other.

In some examples, a pixel unit of the display area AA may include three sub-pixels which are a red sub-pixel, a green sub-pixel, and a blue sub-pixel respectively. However, the present embodiment is not limited thereto. In some examples, one pixel unit may include four sub-pixels, and the four sub-pixels are a red sub-pixel, a green sub-pixel, a blue sub-pixel, and a white sub-pixel respectively.

In some examples, a shape of a sub-pixel may be a rectangle, a rhombus, a pentagon, or a hexagon. When one pixel unit includes three sub-pixels, the three sub-pixels may be arranged in parallel in a horizontal direction, in parallel in a vertical direction, or in a delta-shaped arrangement. When one pixel unit includes four sub-pixels, the four sub-pixels may be arranged in parallel in a horizontal direction, in parallel in a vertical direction, or in a shape forming a square. However, the present embodiment is not limited thereto.

In some examples, one sub-pixel may include a pixel circuit and a light emitting element electrically connected with the pixel circuit. The pixel circuit may include a plurality of transistors and at least one capacitor. For example, the pixel circuit may have a 3T1C, 4T1C, 5T1C, 5T2C, 6T1C, 7T1C, or 8T1C structure. In the above-mentioned circuit structures, T refers to a thin film transistor, C refers to a capacitor, a number before T represents a quantity of thin film transistors in the circuit, and a number before C represents a quantity of capacitors in the circuit. In some examples, the plurality of transistors in the pixel circuit may be P-type transistors or may be N-type transistors. Use of a same type of transistors in the pixel circuit may simplify a process flow, reduce process difficulties of the display panel, and improve a yield of products. In some other examples, the plurality of transistors in the pixel circuit may include a P-type transistor and an N-type transistor.

In some examples, low temperature poly silicon thin film transistors, or oxide thin film transistors, or both a low temperature poly silicon thin film transistor and an oxide thin film transistor may be used as the plurality of transistors in the pixel circuit. Low Temperature Poly Silicon (LTPS) is used for an active layer of a low temperature poly silicon thin film transistor and an oxide semiconductor (Oxide) is used for an active layer of an oxide thin film transistor. The low temperature poly silicon thin film transistor has advantages such as a high migration rate and fast charging, and the oxide thin film transistor has advantages such as a low leakage current. The low temperature poly silicon thin film transistor and the oxide thin film transistor are integrated on one display substrate, that is, an LTPS+Oxide (LTPO for short) display substrate, advantages of both the low temperature poly silicon thin film transistor and the oxide thin film transistor may be utilized, so that low-frequency drive can be achieved, power consumption can be reduced, and display quality can be improved.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, etc. under driving of a pixel circuit corresponding to the light emitting element. A color of light emitted by the light emitting element may be determined as required. In some examples, the light emitting element may include an anode, a cathode, and an organic light emitting layer located between the anode and the cathode. The anode of the light emitting element may be electrically connected to a corresponding pixel circuit. However, the present embodiment is not limited thereto.

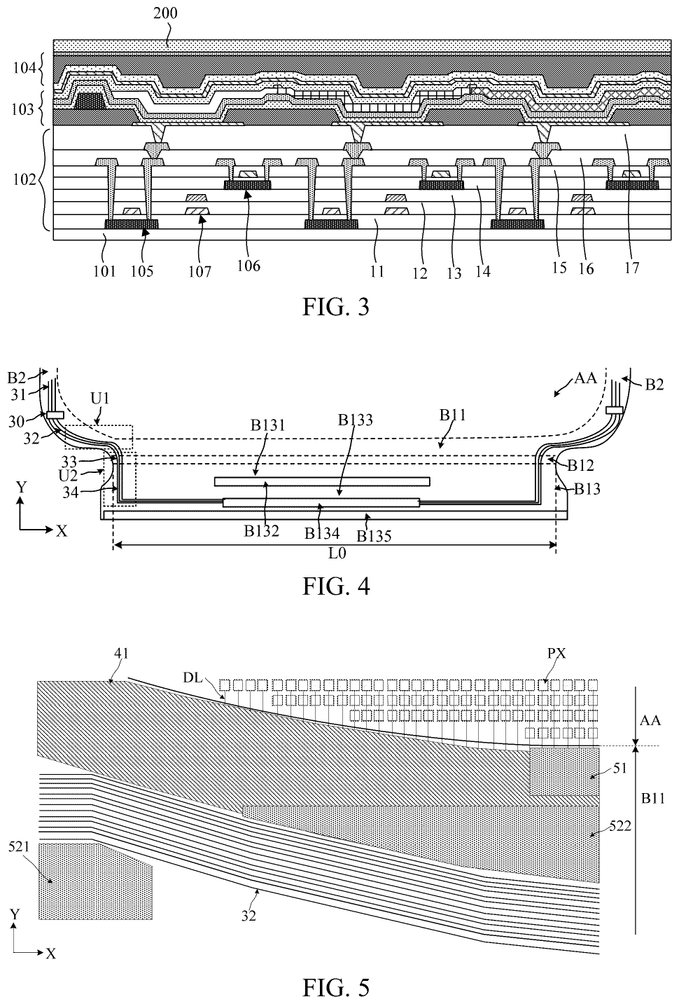

FIG. 3 is a schematic diagram of a partial sectional structure of a display area of a display substrate. FIG. 3 illustrates structures of three sub-pixels of the display substrate. In this example, it will be illustrated by taking an LTPO display substrate as an example. The multiple transistors in the pixel circuit may be Low Temperature Poly-silicon thin film transistors and oxide thin film transistors.

In some example, as shown in FIG. 3, in a direction perpendicular to the display substrate, the display substrate may include: a base substrate 101, and a circuit structure layer 102, a light emitting structure layer 103, an encapsulation structure layer 104 and an encapsulation cover plate 200 that are sequentially disposed on the base substrate 101. In some possible implementations, the display substrate may include other film layers, such as a post spacer, a touch structure layer, which are not limited in the present disclosure herein.

In some examples, the base substrate 101 may be a rigid substrate, such as a glass substrate; or, it may be a flexible substrate, for example, made from an insulation material, such as resin. In addition, the base substrate may be in a single-layer structure or a multi-layer structure. When the base substrate is in a multi-layer structure, an inorganic material such as silicon nitride, silicon oxide, and silicon oxynitride may be arranged between a plurality of layers as a single layer or multiple layers. However, the present embodiment is not limited thereto.

In some examples, a circuit structure layer 102 of each sub-pixel may include a plurality of transistors and a storage capacitor constituting a pixel circuit, and in FIG. 3, it is illustrated by taking one low temperature poly silicon thin film transistor (for example, a first transistor 105), one oxide thin film transistor (for example, a second transistor 106), and one storage capacitor (for example, a first capacitor 107) included in each sub-pixel as an example. In some possible implementations, the circuit structure layer 102 of each sub-pixel may include: a first semiconductor layer (including, for example, an active layer of the low temperature poly silicon thin film transistor) disposed on the base substrate 101; a first insulation layer 11 (or referred to as a first gate insulation layer) covering the active layer; a first gate metal layer (including, for example, a gate electrode of the low temperature poly silicon thin film transistor and a first capacitor electrode of the storage capacitor) disposed on the first insulation layer 11; a second insulation layer 12 (or referred to as a second gate insulation layer) covering the first gate metal layer; a second gate metal layer (including, for example, a second capacitor electrode of the storage capacitor) disposed on the second insulation layer 12; a third insulation layer 13 (or referred to as a third gate insulation layer) covering the second gate metal layer; a second semiconductor layer (including, for example, an active layer of the oxide thin film transistor) disposed on the third insulation layer 13; a fourth insulation layer 14 (or referred to as a fourth gate insulation layer) covering the second semiconductor layer; a third gate metal layer (including, for example, a gate electrode of the oxide thin film transistor) disposed on the fourth insulation layer 14; a fifth insulation layer 15 (or referred to as an interlayer insulation layer) covering the third gate metal layer; a first source-drain metal layer (including, for example, source electrodes and drain electrodes of the low temperature poly silicon thin film transistor and the oxide thin film transistor) disposed on the fifth insulation layer 15; a sixth insulation layer 16 (or referred to as a first planarization layer) covering the aforementioned structures; a second source-drain metal layer (including, for example, a pixel connection electrode with an anode of a light emitting element) disposed on the sixth insulation layer 16; a seventh insulation layer 17 (or referred to as a second planarization layer) covering the second source-drain metal layer. The fifth insulation layer 15 is provided with a first pixel via and a second pixel via. The fifth insulation layer 15, the fourth insulation layer 14, the third insulation layer 13, the second insulation layer 12, and the first insulation layer 11 within the first pixel via are removed to expose a surface of the first semiconductor layer, and a source electrode and a drain electrode of the low temperature poly silicon thin film transistor may be connected with the active layer through the first pixel via, respectively. The fifth insulation layer 15 and the fourth insulation layer 14 within the second pixel via may be removed to expose a surface of the second semiconductor layer, and a source electrode and a drain electrode of the oxide thin film transistor may be connected with the active layer through the second pixel via, respectively. The sixth insulation layer 16 is provided with a third pixel via and a pixel connection electrode located in the second source-drain metal layer may be electrically connected with a transistor of the pixel circuit through the third pixel via. The seventh insulation layer 17 is provided with a fourth pixel via, and an anode of the light emitting element may be electrically connected with the pixel connection electrode located in the second source-drain metal layer through the fourth pixel via.

In some examples, as shown in FIG. 3, the first insulation layer 11 to the fifth insulation layer 15 may be made of an inorganic insulation material, and the sixth insulation layer 16 and the seventh insulation layer 17 may be made of an organic insulation material. However, the present embodiment is not limited thereto.

In some examples, as shown in FIG. 3, the light emitting structure layer 103 may include an anode layer, a pixel definition layer, an organic light emitting layer, and a cathode. The anode layer may include the anode of the light emitting element, the anode may be disposed on the seventh insulation layer 17 and connected with the pixel connection electrode through the fourth pixel via provided on the seventh insulation layer 17. The pixel definition layer is disposed on the anode layer and the seventh insulation layer 17, and a pixel opening is provided on the pixel definition layer and exposes at least a portion of a surface of the anode. The organic light emitting layer is at least partially disposed in the pixel opening and is connected with the anode. The cathode is disposed in the organic light emitting layer and is connected with the organic light emitting layer; and the organic light emitting layer emits light of a corresponding color under drive of the anode and the cathode.

In some examples, as shown in FIG. 3, the encapsulation structure layer 104 may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is disposed between the first encapsulation layer and the third encapsulation layer, which can ensure that external moisture cannot enter the light emitting structure layer 103.

In some examples, the organic light emitting layer may at least include a hole injection layer, a hole transport layer, a light emitting layer and a hole block layer which are stacked on the anode. In some examples, the hole injection layers of all sub-pixels may be connected together to form a common layer. The hole transport layers of all sub-pixels may be connected together to form a common layer. Light emitting layers of adjacent sub-pixels may be slightly overlapped or isolated, and the hole block layers may be connected together to form a common layer. However, the present embodiment is not limited thereto.

In some implementations, with increasing application of OLED panels, demands for narrow bezels are becoming broader and broader. In small-size display products, narrowing of rounded corners has gradually become a trend. However, a lower rounded corner region includes a design with a plurality of lead-out traces, especially for the LTPO display substrate, where a quantity of lead-out signal lines is large, which makes it difficult to narrow the lower rounded corner.

The present embodiment provides a display substrate including a base substrate and a plurality of first lead-out signal lines. The base substrate includes a display area and a peripheral area surrounding the display area, and the peripheral area includes a first bezel region located on one side of the display area. The plurality of first lead-out signal lines are located in the first bezel region. At least one first lead-out signal line of the plurality of first lead-out signal lines includes a first trace, a second trace, and a third trace which are stacked. The second trace is electrically connected with the first trace and the third trace. An orthographic projection of the first trace on the base substrate, an orthographic projection of the second trace on the base substrate, and an orthographic projection of the third trace on the base substrate at least partially overlap.

In the display substrate according to the present embodiment, an effect of reducing trace load and narrowing wiring space of the first bezel region can be achieved by adopting the stacked design of three layers of traces for at least one first lead-out signal line in the first bezel region, thereby effectively reducing a lower rounded corner bezel and realizing the narrowing of the lower rounded corner bezel.

In some exemplary embodiments, the peripheral area may further include a second bezel region located on two sides of the first bezel region, and the plurality of first lead-out signal lines may include a plurality of first drive lead-out signal lines. The display substrate further includes: a plurality of sub-pixels and a plurality of gate lines located in the display area, and a plurality of shift registers located in the second bezel region. The plurality of gate lines are electrically connected with the plurality of sub-pixels. The plurality of shift registers are electrically connected with the plurality of gate lines, and the plurality of shift registers are electrically connected with the plurality of first drive lead-out signal lines. In this example, by disposing the plurality of first drive lead-out signal lines in the first bezel region in a stacked structure of three layers of traces, the trace load can be reduced, and the wiring space in the first bezel region can be narrowed.

In some exemplary embodiments, the display substrate may further include a plurality of data lines located in the display area. The plurality of first lead-out signal lines may include a plurality of first data lead-out lines located in the first bezel region, and the plurality of first data lead-out lines are electrically connected with a plurality of data lines in the display area. The plurality of first data lead-out lines are located between the plurality of first drive lead-out signal lines in the first bezel region. For example, the plurality of first drive lead-out signal lines may be divided into two groups, and the plurality of first data lead-out lines may be located between the two groups of first drive lead-out signal lines. In this example, by disposing the plurality of first data lead-out lines in the first bezel region with a stacked structure of three layers of traces, the wiring space in the first bezel region can be further narrowed, which it is beneficial to realizing the narrowing of a lower rounded corner bezel.

In some exemplary implementations, the first bezel region may include a first sub-region, a bent region, and a second sub-region sequentially disposed in a direction away from the display area. The plurality of first drive lead-out signal lines may be located in the first sub-region. By reducing sizes of the first drive lead-out signal lines located in the first sub-region, the narrowing of the lower rounded corner bezel can be achieved.

In some exemplary embodiments, the display substrate further includes a plurality of drive connection lines located in the bent region. The plurality of drive connection lines are electrically connected with the plurality of first drive lead-out signal lines, and the plurality of drive connection lines are on a side of the plurality of first drive lead-out signal lines away from the base substrate.

In some exemplary embodiments, the display substrate further includes a plurality of second drive lead-out signal lines located in the second sub-region. The plurality of second drive lead-out signal lines are electrically connected with a plurality of first drive lead-out signal lines through a plurality of drive connection lines. In some examples, at least one second drive lead-out signal line may include a fourth trace, a fifth trace, and a sixth trace that are stacked. The fourth trace and the first trace may be disposed in a same layer, the fifth trace and the second trace may be disposed in a same layer, and the sixth trace and the third trace may be disposed in a same layer. In this example, by disposing the second drive lead-out signal lines with a stacked structure, it is beneficial to reducing a length of the second sub-region along a first direction, and has positive benefits for the space and shape of the display substrate.

In some exemplary embodiments, the first drive lead-out signal line may have a first trace located in the first gate metal layer, a second trace located in the second gate metal layer, and a third trace located in the third gate metal layer. The first gate metal layer, the second gate metal layer, and the third gate metal layer may be located in different layers. This example is beneficial to manufacturing of the display substrate, and avoids addition of new traces for manufacturing the film layers.

Solutions of the embodiments will be described below through some examples. In the following example, it is illustrated by taking the display substrate is a flexible substrate as an example.

FIG. 4 is a schematic diagram of a first bezel region according to at least one embodiment of the present disclosure. In some examples, as shown in FIG. 4, the first bezel region may include a first sub-region B11, a bent region B12, and a second sub-region B13 in a direction away from the display area AA. Two ends of the first sub-region B11 in the first direction X may communicate with the second bezel region B2 on its left side and right side. For example, a communication region between the first sub-region B11 and of the second bezel region B2 on the left side may form a left lower rounded corner, and a communication region between the first sub-region B11 and the second bezel region B2 on the right side may form a right lower rounded corner. The first sub-region B11 may also be referred to as a first fan-out region. The first sub-region B11 may be connected to the display area AA, and includes at least a first power supply line, a second power supply line, a plurality of first data lead-out lines, and a plurality of first drive lead-out signal lines 32. The plurality of first data lead-out lines may be configured to be electrically connected with the data lines of the display area AA and extend in a fan-out trace manner. The first power supply line may be configured to be connected to a high level power supply line in the display area AA, and the second power supply line may be configured to be connected to a low-level power supply line in the second bezel region B2. The second bezel region B2 may be provided with a gate drive circuit, the gate drive circuit may include a plurality of shift registers, and the gate drive circuit may be electrically connected with a plurality of drive signal lines 31, and the plurality of drive signal lines 31 may be electrically connected with the plurality of first drive lead-out signal lines 32 through a first electrostatic discharge circuit 30. The first electrostatic discharge circuit 30 may be located at a position in the second bezel region B2 close to a lower rounded corner region. For example, the plurality of first drive lead-out signal lines may be configured to provide a clock signal and a voltage signal to the gate drive circuit in the second bezel region B2. However, the present embodiment is not limited thereto.

In some examples, as shown in FIG. 4, the bent region B12 may be connected between the first sub-region B11 and the second sub-region B13. The bent region B12 may include a composite insulation layer provided with a groove, and the groove is configured to allow the first bent region to be bent to a back of the display area AA. For example, the bent region B12 may include at least a plurality of drive connection lines 33 electrically connected with the plurality of first drive lead-out signal lines 32 and a plurality of data connection lines electrically connected with the plurality of first data lead-out lines.

In some examples, as illustrated in FIG. 4, the second sub-region B13 may include a second fan-out region B131, a first circuit region B132, a third fan-out region B133, a drive chip region B134, and a bonding pin region B135, which are sequentially disposed in the direction away from the display area AA. The second fan-out region B131 may include a plurality of fan-out traces (for example, including: a plurality of second drive lead-out signal lines, a plurality of second data lead-out lines, wherein the plurality of second data lead-out lines may be located between the plurality of second drive lead-out signal lines). The first circuit region B132 may include at least a second electrostatic discharge circuit which may be configured to prevent electrostatic damage to the display substrate by eliminating static electricity. The third fan-out region B133 may include a plurality of fan-out traces (e.g., include a plurality of third data lead-out lines). The drive chip region B134 may be provided with a drive chip (IC, Integrated Circuit). The drive chip region B134 may include a plurality of drive chip pins. The drive chip may be electrically connected with the data lines of the display area AA through the drive chip pins, the data lead-out lines (including, for example, the third data lead-out lines, the second data lead-out lines, and the first data lead-out lines), may be configured to generate signals required for driving the sub-pixels, and provide the drive signals to the data lines of the display area. For example, a drive signal may be a data signal that drives a sub-pixel to emit light. The bonding pin region B135 may include a plurality of bonding pins, which may be configured to be bonded to at least one corresponding circuit board (e.g., a Flexible Printed Circuit board (FPC)). The drive chip pins in the drive chip region B134 may be electrically connected with the bonding pins in the bonding pin region B135 through a pin connection line.

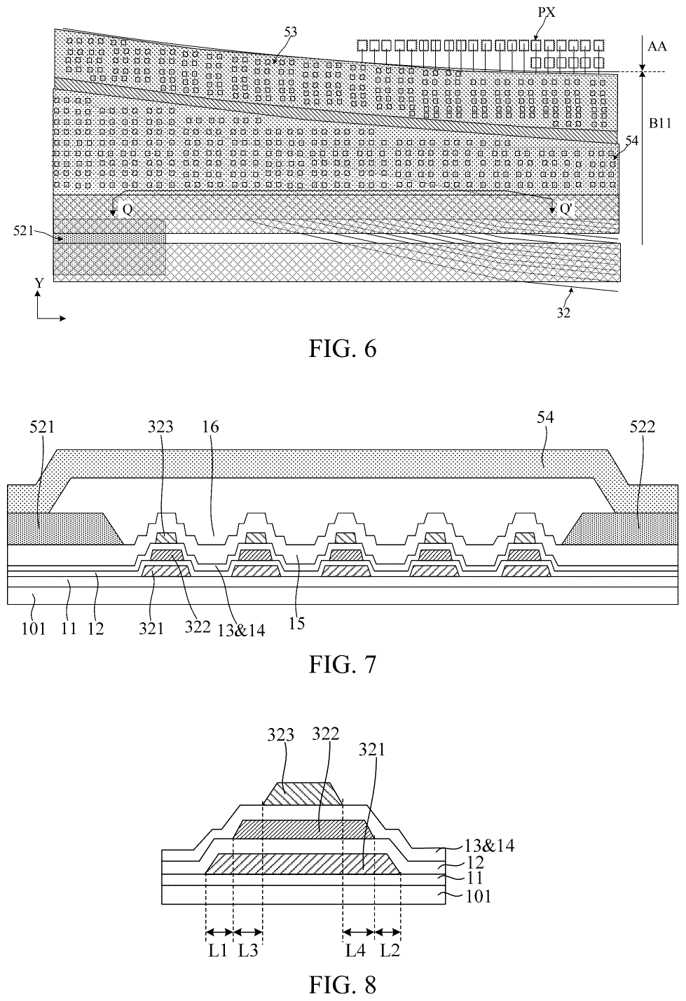

FIG. 5 and FIG. 6 are schematic partial enlarged diagrams of region U1 in FIG. 4. FIG. 5 is a partial schematic diagram of a region U1 after a first source-drain metal layer is formed. FIG. 6 is a partial schematic diagram of the region U1 after a second source-drain metal layer is formed. In FIGS. 5 and 6, a plurality of first data lead-out lines 41 are schematically illustrated as a whole. The plurality of first data lead-out lines 41 may be electrically connected with data lines DL extending from the display area AA, and be configured to provide data signals to the data lines DL. Cross grid shadow areas in FIG. 6 show regions where a sixth insulation layer has been removed. FIG. 7 is a schematic partial cross-sectional view taken along a Q-Q′ direction in FIG. 6. In FIG. 7, it is illustrated by taking a cross-sectional structure of five first drive lead-out signal lines as an example. In this example, a width of a trace is a length in a direction perpendicular to an extension length direction in an extension plane parallel to the traces.

In some examples, as illustrated in FIGS. 4 to 6, the plurality of first drive lead-out signal lines 32 may be sequentially arranged in the direction away from the display area AA, and may extend from the lower rounded corner region to the bent region B12. For example, the plurality of first drive lead-out signal lines 32 may include: a plurality of clock signal lines (including, for example, a first clock signal line GCK that provides a first clock signal to the gate drive circuit and a second clock signal line GCB that provides a second clock signal), a plurality of voltage lines (including, for example, a first voltage line VGH1, a second voltage line VGH2, a third voltage line VGL1, and a fourth voltage line VGL2 configured to provide voltages to the gate drive circuit). In this example, it is illustrated by taking the plurality of first lead-out signal lines with a design that the three layers of traces are the plurality of first drive lead-out signal lines as an example. In some other examples, the plurality of first lead-out signal lines may further include: a plurality of first data lead-out lines. Or, the plurality of first lead-out signal lines may further include: a plurality of initial signal lines (including, for example, a first initial signal line INIT1, a second initial signal line INIT2, and a third initial signal line INIT3 that provide initial signals to the pixel circuits of the display area). Or, the plurality of first lead-out signal lines may further include a plurality of first data lead-out lines and a plurality of initial signal lines. The present embodiment is not limited thereto.

In some examples, as shown in FIGS. 5 and 6, the first sub-region B11 may include a first power supply line 51 and a second power supply line. The first power supply line 51 and the second power supply line may be disposed in a same layer, and the second power supply line may be on a side of the first power supply line 51 away from the display area AA. The second power supply line may include a first sub-power supply line 521 and a second sub-power supply line 522 in the first sub-region B11. The first sub-power supply line 521 may extend to the second bezel region along the lower rounded corner region, and the second sub-power supply line 522 may extend to a side to the bent region B12. Orthographic projections of the first sub-power supply line 521 and the second sub-power supply line 522 of the first sub-region B11 on the base substrate may not be overlapped with orthographic projections of the plurality of first drive lead-out signal lines 32 on the base substrate. In other words, the first sub-power supply line 521 and the second sub-power supply line 522 may be disposed across opposite sides of the plurality of first drive lead-out signal lines 32 in a first direction X.

In some examples, as shown in FIGS. 5 and 6, the first sub-region B11 may further include a first power supply auxiliary connection line 53 and a second power supply auxiliary connection line 54. The first power supply auxiliary connection line 53 and the second power supply auxiliary connection line 54 may be disposed in a same layer, and may be on a side of the first power supply line 51 and the second power supply line away from the base substrate. The first power supply auxiliary connection line 53 may be electrically connected with the first power supply line 51 whose orthographic projection is overlapped with that of the first power supply auxiliary connection line 53 through a via provided in the sixth insulation layer. A portion of the second power supply auxiliary connection line 54 close to the display area may be electrically connected with the first sub-power supply line 521 and the second sub-power supply line 522 whose orthographic projections are overlapped with an orthographic projection of the said portion through a via provided in the sixth insulation layer, and a portion of the second power supply auxiliary connection line 54 away from the display area (corresponding to a removed portion of the sixth insulation layer) may be directly electrically connected with the first sub-power supply line 521 and the second sub-power supply line 522 whose orthographic projections are overlapped with an orthographic projection of the said portion.

In some examples, as shown in FIG. 6, the first power supply auxiliary connection line 53 and the second power supply auxiliary connection line 54 may be provided with a plurality of vias, and by providing the plurality of vias, the first power supply auxiliary connection line 53 and the second power supply auxiliary connection line 54 can be avoided from coming into contact with the sixth insulation layer in a large area, resulting in film explosion of the sixth insulation layer, and the manufacturing effect of the display substrate can be improved.

In some examples, as illustrated in FIGS. 6 and 7, they are illustrated by taking one first drive lead-out signal line 32 as an example, wherein the first drive lead-out signal line 32 may include a first trace 321, a second trace 322, and a third trace 323 which are stacked. The first trace 321 may be on a side of the second trace 322 close to the base substrate 10, and the third trace 323 may be on a side of the second trace 322 away from the base substrate 10. The second insulation layer 12 may be provided between the first trace 321 and the second trace 322, and the third insulation layer 13 and the fourth insulation layer 14 may be provided between the second trace 322 and the third trace 323. Orthographic projections of the first trace 321, the second trace 322, and the third trace 323 on the base substrate 101 may at least partially overlap. In this example, the first trace 321 may be located in the first gate metal layer, the second trace 322 may be located in the second gate metal layer, and the third trace 323 may be located in the third gate metal layer. In this example, in the manufacturing process of the pixel circuit in the display area, three stacked traces of the first drive lead-out signal line can be synchronously manufactured, and the manufacturing process can be simplified. In this example, by adopting a stacked design for the first drive lead-out signal line, it is possible to achieve a purpose of reducing a line width of the first drive lead-out signal line, thereby reducing the wiring space. In some examples, the first data lead-out lines 41 may be located in the first gate metal layer or the second gate metal layer, and adjacent first data lead-out lines 41 among the plurality of first data lead-out lines 41 may be located in different layers. For example, the plurality of first data lead-out lines 41 are arranged in a manner in which the plurality of first data lead-out lines 41 are alternately disposed in the first gate metal layer and the second gate metal layer. However, the present embodiment is not limited thereto. In some other examples, at least one first data lead-out line 41 may adopt a same stacked design of three layers of traces as the first drive lead-out signal lines, which may further narrow the wiring space of the first bezel region.

In some examples, as shown in FIG. 7, the third trace 323 may be covered by a fifth insulation layer 15. Since the fifth insulation layer 15 is made of an inorganic insulation material, the stacked design of the first drive lead-out signal lines is likely to cause a large segment difference, and the fifth insulation layer 15 made of the inorganic insulation material is likely to be broken, thereby causing occurrence of a short circuit. In this example, the second power supply line located in the first source-drain metal layer is disconnected, that is, it is disconnected into the first sub-power supply line 521 and the second sub-power supply line 522 above the first drive lead-out signal line. The first sub-power supply line 521 and the second sub-power supply line 522 may be electrically connected through the second power supply auxiliary connection line 54 located in the second source-drain metal layer, thereby realizing transmission of a second power supply signal in the first bezel region, ensuring a continuity of the transmission of the second power supply signal, and avoiding the occurrence of short circuit.

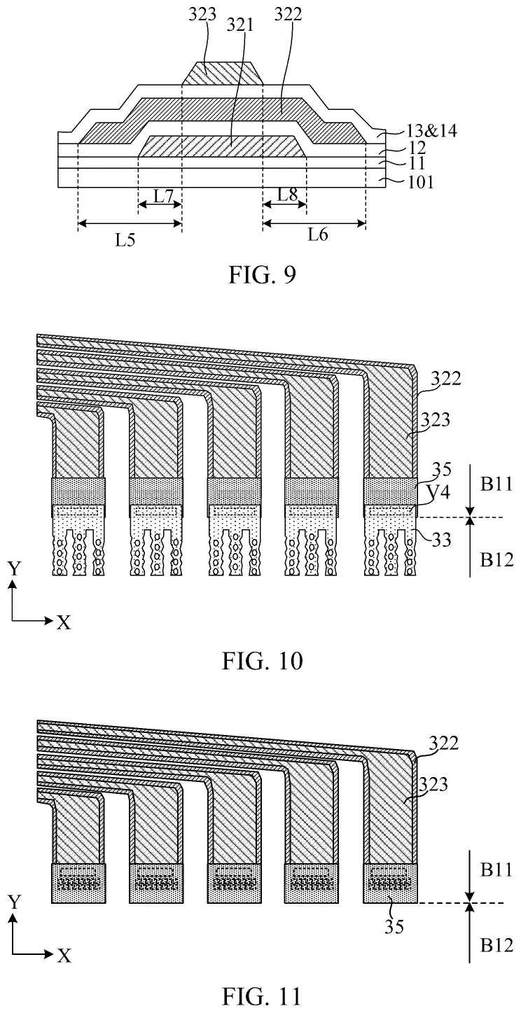

FIGS. 8 and 9 are schematic cross-sectional views of a first drive lead-out signal line according to at least one embodiment of the present disclosure. In FIGS. 8 and 9, it is illustrated by taking only one first drive lead-out signal line as an example.

In some examples, as shown in FIG. 8, a width of the second trace 322 of the first drive lead-out signal line may be greater than a width of the third trace 323, and a width of the first trace 321 may be greater than the width of the second trace 322. The first trace 321, second trace 322, and third trace 323 which are stacked form a positive trapezoidal structure in a cross-sectional direction. A distance by which a left side edge of the first trace 321 protrudes from a left side edge of the second trace 322 may be L1, and a distance by which the left side edge of the second trace 322 protrudes from a left side edge of the third trace 323 may be L3. A distance by which a right side edge of the first trace 321 protrudes from a right side edge of the second trace 322 may be L2, and a distance by which the right side edge of the second trace 322 protrudes from a right side edge of the third trace 323 may be L4. For example, L1 may be approximately equal to L2, and L3 may be approximately equal to L4. For example, L1 may be greater than or equal to 1 micron, and L3 may be greater than or equal to 2 microns. The stacked design in this example can ensure stability of the structure of traces.

In some examples, as shown in FIG. 9, the width of the second trace 322 of the first drive lead-out signal line may be greater than the width of the first trace 321, and the width of the first trace 321 may be greater than the width of the third trace 323. A distance by which the left side edge of the second trace 322 protrudes from the left side edge of the third trace 323 may be L5, and a distance by which the left side edge of the second trace 322 protrudes from the left side edge of the first trace 321 may be L7. A distance by which the right side edge of the second trace 322 protrudes from the right side edge of the third trace 323 may be L6, and a distance by which the right side edge of the second trace 322 protrudes from the right side edge of the first trace 321 may be L8. For example, L5 may be approximately equal to L6, and L7 may be approximately equal to L8. For example, L7 may be greater than or equal to 1 micron and L6 may be greater than or equal to 2 microns. The stacked design in this example may ensure that the third trace may be routed at relatively flat positions on the second trace.

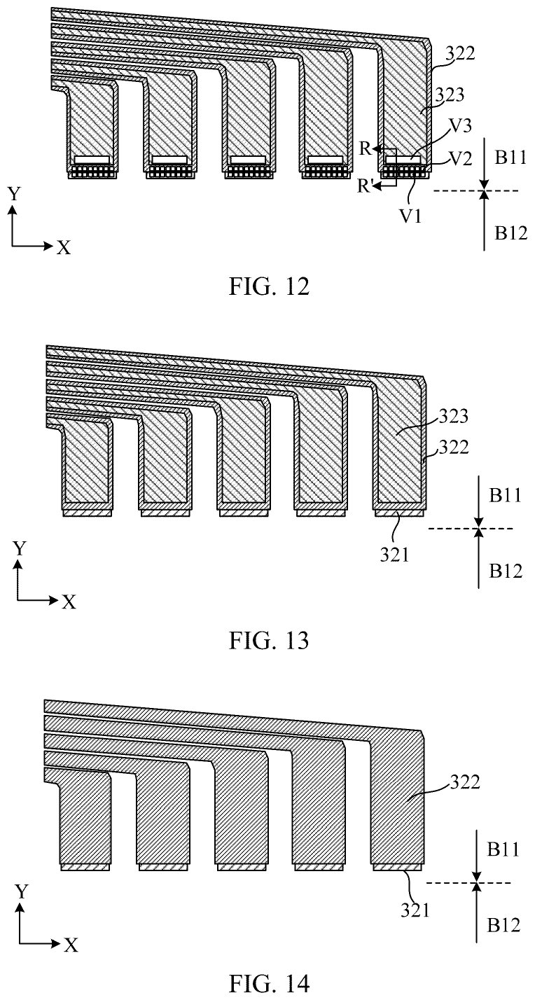

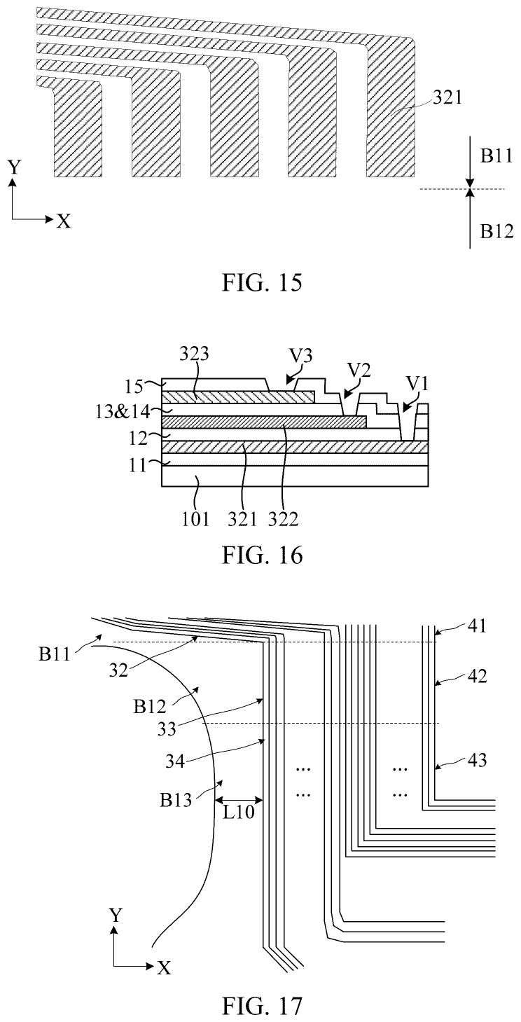

FIG. 10 is a schematic diagram of a connection between a first drive lead-out signal line in a first sub-region and a bent connection line in a bent region according to at least one embodiment of the present disclosure. FIG. 11 is a schematic diagram of a first bezel region after a first source-drain metal layer is formed in FIG. 10. FIG. 12 is a schematic diagram of a first bezel region after a fifth insulation layer is formed in FIG. 10. FIG. 13 is a schematic diagram of a first bezel region after a third gate metal layer is formed in FIG. 10. FIG. 14 is a schematic diagram of a first bezel region after a second gate metal layer is formed in FIG. 10. FIG. 15 is a schematic diagram of a first bezel region after a first gate metal layer is formed in FIG. 10. FIG. 16 is a schematic partial cross-sectional view along a R-R′ direction in FIG. 12.

In some examples, as shown in FIGS. 10 to 15, extension directions of the first trace 321, the second trace 322, and the third trace 323 of the first drive lead-out signal line may be substantially the same. One end of the first trace 321 close to the bent region B12 may protrude from the second trace 322. One end of the second trace 322 close to the bent region B12 may protrude from the third trace 323. A plurality of first connection electrodes 35 may be disposed in a boundary region between the first sub-region B11 and the bent region B12. The first connection electrodes 35 may be located on the first source-drain metal layer and arranged sequentially along the first direction X. As shown in FIGS. 11, 12, and 16, the first connection electrodes 35 may be electrically connected with the first trace 321 through a plurality of first vias V1, may be electrically connected with the second trace 322 through a plurality of second vias V2, and may be electrically connected with the third trace 323 through a third via V3. Electrical connections of the first trace 321, the second trace 322, and the third trace 323 are achieved through the first connection electrode 35. The second insulation layer 12, the third insulation layer 13, the fourth insulation layer 14, and the fifth insulation layer 15 within a first via V1 may be removed to expose a surface of the first trace 321. The third insulation layer 13, the fourth insulation layer 14, and the fifth insulation layer 15 within the second via V2 may be removed to expose a surface of the second trace 322. The fifth insulation layer 15 within the third via V3 may be removed to expose a surface of the third trace 323. In some examples, as shown in FIG. 12, the plurality of first vias V1 may be aligned and arranged in the first direction X, and the plurality of second vias V2 may be aligned and arranged in the first direction X. The present embodiment is not limited thereto.

In some examples, as shown in FIG. 10, a bent connection line 33 located in the second source-drain metal layer may be electrically connected with a first connection electrode 35 located in the first source-drain metal layer through a fourth via V4. The bent connection line 33 may be a bent trace, thereby enabling bendability of the bent region B12.

FIG. 17 is a partial schematic diagram of a region U2 in FIG. 4. In some examples, as shown in FIG. 17, the second sub-region B13 may include a plurality of second drive lead-out signal lines 34. The plurality of second drive lead-out signal lines 34 may be electrically connected with the plurality of first drive lead-out signal lines 32 in the first sub-region B11 through the bent connection lines 33.

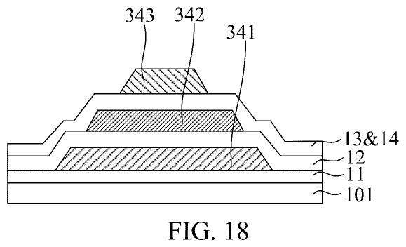

FIG. 18 is a partial cross-sectional schematic diagram of a second drive lead-out signal line according to at least one embodiment of the present disclosure. In this example, it is illustrated by taking a cross-sectional structure of a second drive lead-out signal line as an example. In some examples, as shown in FIG. 18, the second drive lead-out signal line 34 may include a fourth trace 341, a fifth trace 342, and a sixth trace 343 which are stacked. Orthographic projections of the fourth trace 341, the fifth trace 342, and the sixth trace 343 on the base substrate 101 at least partially overlap. For example, the fourth trace 341 and the first trace of the first drive lead-out signal line may be disposed in a same layer, the fifth trace 342 and the second trace of the first drive lead-out signal line may be disposed in a same layer, and the sixth trace 343 and the third trace of the first drive lead-out signal line may be disposed in a same layer. The structure of the second drive lead-out signal line can be referred to as the structure of the first drive lead-out signal line, and thus the description thereof will not be repeated here. As for the connection mode between the second drive lead-out signal line 34 and the bent connection line 33, reference can be made to the connection mode between the first drive lead-out signal line 32 and the bent connection line 33. For example, three traces of the second drive lead-out signal line 34 may be electrically connected with the bent connection line 33 located in the second source-drain metal layer through one connection electrode located in the first source-drain metal layer, and thus the description thereof will not be repeated here.

In some examples, as shown in FIG. 17, the bent region B12 may further include a plurality of data connection lines 42. The plurality of first data lead-out lines 41 in the first sub-region B11 may be electrically connected with the plurality of second data lead-out lines 43 located in the second sub-region B13 through the plurality of data connection lines 42. The plurality of data connection lines 42 may be on a side of the plurality of bent connection lines 33 away from an edge of the display substrate. The plurality of first data lead-out lines 41 may be located between the plurality of first drive lead-out signal lines 32, and the plurality of second data lead-out lines 43 may be located between the plurality of second drive lead-out signal lines 34. The plurality of data connection lines 42 may be located in the second source-drain metal layer. The plurality of first data lead-out lines 41 and the plurality of second data lead-out lines 43 may be located in the first gate metal layer or the second gate metal layer. Or, adjacent first data lead-out lines 41 may be alternately located in the first gate metal layer and the second gate metal layer, and adjacent second data lead-out lines 43 may be alternately located in the first gate metal layer and the second gate metal layer. In some other examples, the plurality of first data lead-out lines 41 may adopt a structure of three layers of traces stacked. In some other examples, the plurality of second data lead-out lines 43 may adopt a structure of three layers of traces stacked. However, the present embodiment is not limited thereto.

In some examples, by disposing the second drive lead-out signal line in a stacked structure, the width of wiring design can be reduced, the load can be reduced, and the width L0 of the first bezel region along the first direction X can be narrowed (as shown in FIG. 4). A distance between an edge of the second drive lead-out signal line and the first bezel region may be L10, for example, L10 may be about 360 microns, and thus L0 may be reduced by 720 microns. By reducing L0, there can be positive benefits for both space and morphology of the display substrate.

A display device is further provided in at least an embodiment of the present disclosure, which includes the display substrate as described above. The display device may be any product or component with a display function, such as a mobile phone, a tablet computer, a television, a display, a laptop computer, a digital photo frame, or a navigator.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the essence and scope of the technical solutions of the present disclosure, which shall all fall in the scope of the claims of the present application.

1. A display substrate, comprising:
a base substrate comprising a display area and a peripheral area surrounding the display area, wherein the peripheral area comprises a first bezel region located on one side of the display area; and
a plurality of first lead-out signal lines located in the first bezel region; at least one first lead-out signal line of the plurality of first lead-out signal lines comprises a first trace, a second trace, and a third trace which are stacked, wherein the second trace is electrically connected with the first trace and the third trace, and an orthographic projection of the first trace on the base substrate, an orthographic projection of the second trace on the base substrate, and an orthographic projection of the third trace on the base substrate are at least partially overlapped with each other.

2. The display substrate according to claim 1, wherein the peripheral area further comprises a second bezel region located on two sides of the first bezel region; the plurality of first lead-out signal lines comprises a plurality of first drive lead-out signal lines;
the display substrate further comprises:
a plurality of sub-pixels located in the display area;
a plurality of gate lines located in the display area and electrically connected with the plurality of sub-pixels; and
a plurality of shift registers located in the second bezel region and electrically connected with the plurality of gate lines, and the plurality of shift registers are electrically connected with the plurality of first drive lead-out signal lines.

3. The display substrate according to claim 2, further comprising: a plurality of data lines located in the display area;
wherein the plurality of first lead-out signal lines comprise a plurality of first data lead-out lines located in the first bezel region and electrically connected to the plurality of data lines in the display area; and
the plurality of first data lead-out lines are located between the plurality of first drive lead-out signal lines in the first bezel region.

4. The display substrate according to claim 2- or 3, wherein the first bezel region includes: a first sub-region, a bent region, and a second sub-region disposed sequentially along a direction away from the display area; and
the plurality of first drive lead-out signal lines are located in the first sub-region.

5. The display substrate according to claim 4, further comprising: a plurality of drive connection lines located in the bent region; wherein the plurality of drive connection lines are electrically connected with the plurality of first drive lead-out signal lines, and the plurality of drive connection lines are on a side of the plurality of first drive lead-out signal lines away from the base substrate.

6. The display substrate according to claim 5, wherein a drive connection line is electrically connected with a first trace, a second trace, and a third trace of a corresponding first drive lead-out signal line through a first connection electrode; the first connection electrode is on a side of the first trace, the second trace, and the third trace of the corresponding first drive lead-out signal line away from the base substrate.

7. The display substrate according to claim 5, further comprising: a plurality of second drive lead-out signal lines located in the second sub-region;
wherein the plurality of second drive lead-out signal lines are electrically connected with the plurality of first drive lead-out signal lines through the plurality of drive connection lines.

8. The display substrate according to claim 7, wherein at least one second drive lead-out signal line of the plurality of second drive lead-out signal lines comprises: a fourth trace, a fifth trace, and a sixth trace which are stacked; the fourth trace and the first trace are disposed in a same layer, the fifth trace and the second trace are disposed in a same layer, and the sixth trace and the third trace are disposed in a same layer.

9. The display substrate according to claim 1, wherein the third trace of the first lead-out signal line is on a side of the second trace away from the base substrate, and the first trace is on a side of the second trace close to the base substrate; a width of the first trace of the first lead-out signal line is larger than a width of the second trace, and the width of the second trace is larger than a width of the third trace.

10. The display substrate according to claim 1, wherein the third trace of the first lead-out signal line is on a side of the second trace away from the base substrate, and the first trace is on a side of the second trace close to the base substrate; a width of the second trace of the first lead-out signal line is larger than a width of the first trace, and the width of the first trace is larger than a width of the third trace.

11. The display substrate according to claim 1, wherein the first trace of the first lead-out signal line is located in a first gate metal layer, the second trace is located in a second gate metal layer, and the third trace is located in a third gate metal layer; the first gate metal layer, the second gate metal layer, and the third gate metal layer are located in different layers.

12. The display substrate according to claim 4, further comprising: a second power supply line located in the first bezel region; an orthographic projection of the second power supply line on the base substrate is not overlapped with orthographic projections of the plurality of first drive lead-out signal lines on the base substrate in the first sub-region, and the second power supply line is on a side of the plurality of first drive lead-out signal lines away from the base substrate.

13. The display substrate according to claim 12, further comprising: a second power supply auxiliary line located in the first sub-region of the first bezel region; the second power supply line in the first sub-region comprises: a first sub-power supply line and a second sub-power supply line, wherein the first sub-power supply line and the second sub-power supply line are electrically connected through the second power supply auxiliary line; an orthographic projection of the second power supply auxiliary line on the base substrate is at least partially overlapped with the orthographic projections of the plurality of first drive lead-out signal lines on the base substrate.

14. The display substrate according to claim 13, wherein the second power supply auxiliary line is on a side of the first sub-power supply line and the second sub-power supply line away from the base substrate.

15. The display substrate according to claim 14, wherein the second power supply auxiliary line is located in a second source-drain metal layer, the first sub-power supply line and the second sub-power supply line are located in a first source-drain metal layer, and the first source-drain metal layer and the second source-drain metal layer are located in different layers.

16. A display device, comprising the display substrate according to claim 1.

17. The display substrate according to claim 3, wherein the first bezel region includes: a first sub-region, a bent region, and a second sub-region disposed sequentially along a direction away from the display area; and
the plurality of first drive lead-out signal lines are located in the first sub-region.

18. The display substrate according to claim 2, wherein the third trace of the first lead-out signal line is on a side of the second trace away from the base substrate, and the first trace is on a side of the second trace close to the base substrate; a width of the first trace of the first lead-out signal line is larger than a width of the second trace, and the width of the second trace is larger than a width of the third trace.

19. The display substrate according to claim 3, wherein the third trace of the first lead-out signal line is on a side of the second trace away from the base substrate, and the first trace is on a side of the second trace close to the base substrate; a width of the first trace of the first lead-out signal line is larger than a width of the second trace, and the width of the second trace is larger than a width of the third trace.

20. The display substrate according to claim 4, wherein the third trace of the first lead-out signal line is on a side of the second trace away from the base substrate, and the first trace is on a side of the second trace close to the base substrate; a width of the first trace of the first lead-out signal line is larger than a width of the second trace, and the width of the second trace is larger than a width of the third trace.
